(19) United States
(12) Patent Application Publication
(10) Pub. No.: US 2009/0108742 A1
(43) Pub. Date: Apr. 30, 2009

(54) DISPLAY DEVICE

(76) Inventor: Hirofumi KUBOTA, Kanazawa-shi (JP)

Correspondence Address: OBLON, SPIVAK, MCCLELLAND MAIER & NEUSTADT, P.C., 1940 DUKE STREET, ALEXANDRIA, VA, 22314, US

(21) Appl. No.: 12/252,523

(22) Filed: Oct. 16, 2008

(30) Foreign Application Priority Data
Oct. 31, 2007 (JP) 2007-283513

(51) Int. Cl. H01J 1/63

(52) U.S. Cl. 313/504

(57) ABSTRACT

An organic EL element includes an anode, a cathode disposed to be opposed to the anode, an organic active layer disposed between the anode and the cathode, and a carrier injection adjusting layer which is disposed between the anode and the organic active layer and exhibits such varistor characteristics that a conduction current due to an applied voltage varies.

### CROSS-REFERENCE TO RELATED APPLICATIONS

This application is based upon and claims the benefit of priority from prior Japanese Patent Application No. 2007-283513, filed Oct. 31, 2007, the entire contents of which are incorporated herein by reference.

### BACKGROUND OF THE INVENTION

1. Field of the Invention

The present invention relates to a display device, and more particularly to a display device which is configured to include a self-luminous display element.

2. Description of the Related Art

In recent years, organic electroluminescence (EL) display devices have attracted attention as flat-panel display devices. Since the organic EL display device includes an organic EL element which is a self-luminous element, it has such features as a wide viewing angle, small thickness without a need for backlight, low power consumption, and a high responsivity speed.

For these features, attention has been paid to the organic EL display device as a promising candidate for the next-generation flat-panel display device, which will take the place of liquid crystal display devices. The organic EL display device includes, as a display element, an organic EL element in which an organic active layer containing an organic compound with a light-emitting function is held between an anode and a cathode on a substrate.

The organic EL element has a drawback that the light-emission lifetime is short. Various factors of this drawback may be thought. Jpn. Pat. Appln. KOKAI Publication No. H10-228982, for instance, discloses a technique wherein an anode is composed of a two-layer structure comprising a first layer which mainly distributes a current and a second layer which injects holes in a hole transport layer, paying attention to the fact that the occurrence of a non-light-emission part on a light-emitting surface is a degradation of an interface between the anode and hole transport layer, which constitute the organic EL element, or a dark spot. Thereby, the function of hole injection from the anode to the hole transport material is stabilized and the light-emission lifetime is increased.

In order to achieve a long lifetime of the organic EL display device, it is necessary to keep an optimal carrier balance of the light-emitting layer over a wide range of driving current for use in display. However, since the injection characteristics and transport characteristics of holes and electrons vary from material to material, it is difficult to keep an optimal carrier balance over a wide range of driving current, and there arise problems such as a decrease in light emission efficiency and a decrease in lifetime.

### BRIEF SUMMARY OF THE INVENTION

The present invention has been made in consideration of the above-described problems, and the object of the invention is to provide a display device, the lifetime of which can be increased.

According to an aspect of the present invention, there is provided a display device including a self-luminous display element, the display element comprising: an anode; a cathode disposed to be opposed to the anode; an organic active layer disposed between the anode and the cathode; and a carrier injection adjusting layer which is disposed between the anode and the organic active layer and exhibits non-linear resistance characteristics, wherein the carrier injection adjusting layer suppresses injection of holes from the anode into the organic active layer in a manner to maintain a carrier balance with electrons, which are injected from the cathode into the organic active layer, as a voltage, which is applied to the organic active layer, becomes lower.

According to the present invention, the carrier injection adjusting layer is provided between the anode and the organic active layer. The carrier injection adjusting layer has such varistor characteristics that the hole injection is suppressed at a low voltage and the hole injection is increased at a high voltage. Thus, the carrier balance can optimally be kept in the range of driving current, and the light emission efficiency can be increased. Thereby, the lifetime of the device can be increased.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate presently preferred embodiments of the invention, and together with the general description given above and the detailed description of the preferred embodiments given below, serve to explain the principles of the invention.

FIG. 1 schematically shows the structure of an organic EL display device according to an embodiment of the present invention;

FIG. 2 is a cross-sectional view which schematically shows a cross-sectional structure of the organic EL display device shown in FIG. 1;

FIG. 3 is a view for specifically describing an example of the structure of an organic EL element;

FIG. 4 is a graph for explaining an example of varistor characteristics of a carrier injection adjusting layer shown in FIG. 3; and

FIG. 5 is a graph showing a comparison result of current/efficiency characteristics between the embodiment (with a carrier injection adjusting layer) and a comparative example (without a carrier injection adjusting layer).

### DETAILED DESCRIPTION OF THE INVENTION

A display device according to an embodiment of the present invention will now be described with reference to the accompanying drawings. In this embodiment, a self-luminous display device, for instance, an organic EL (electroluminescence) display device, is described as an example of the display device.

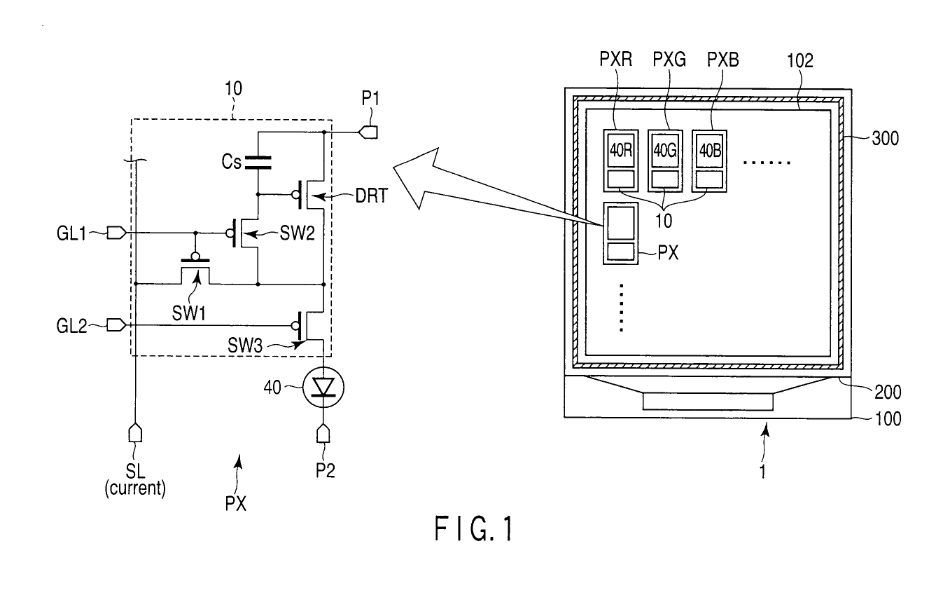

As shown in FIG. 1, an organic EL display device 1 includes an array substrate 100 having an active area 102 which displays an image. The active area 102 is composed of a plurality of pixels PX which are arrayed in a matrix. FIG. 1 shows the organic EL display device 1 of a color display type, by way of example, and the active area 102 is composed of a plurality of kinds of color pixels, for instance, a red pixel PXR, a green pixel PXG and a blue pixel PXB corresponding to the three primary colors.

At least the active area 102 of the array substrate 100 is sealed by a sealing member 200. Specifically, the array substrate 100 and sealing member 200 are attached to each other via a sealant 300 which is disposed in a frame shape so as to surround the active area 102. The sealant 300 may be a photosensitive resin (e.g. ultraviolet-curing resin) or frit glass.

Each of the pixels PX (R, G, B) includes a pixel circuit 10 and a display element 40 which is driven and controlled by the pixel circuit 10. Needless to say, the pixel circuit 10 shown in FIG. 1 is merely an example, and pixel circuits with other structures are applicable. In the example shown in FIG. 1, the pixel circuit 10 is configured to include a driving transistor DRT, a first switch SW1, a second switch SW2, a third switch SW3 and a storage capacitance element Cs. The driving transistor DRT has a function of controlling the amount of electric current that is supplied to the display element 40. The first switch SW1 and the second switch SW2 function as a sample/hold switch. The third switch SW3 has a function of controlling the supply of driving current from the driving transistor DRT to the display element 40, that is, the turning on/off of the display element 40. The storage capacitance element Cs has a function of retaining a gate-source potential of the driving transistor DRT.

The driving transistor DRT is connected between a high-potential power supply line P1 and the third switch SW3. The display element 40 is connected between the third switch SW3 and a low-potential power supply line P2. The gate electrodes of the first switch SW1 and second switch SW2 are connected to a first gate line GL1. The gate electrode of the third switch SW3 is connected to a second gate line GL2. The source electrode of the first switch SW1 is connected to a video signal line SL. The driving transistor DRT, first switch SW1, second switch SW2 and third switch SW3 are composed of, for example, thin-film transistors, and their semiconductor layers are formed of polysilicon in this example.

In the case of this circuit structure, the first switch SW1 and the second switch SW2 are turned on, on the basis of the supply of an ON signal from the first gate line GL1. An electric current flows from the high-potential power supply line P1 to the driving transistor DRT in accordance with the amount of electric current flowing in the video signal line SL, and the storage capacitance element Cs is charged in accordance with the electric current flowing in the driving transistor DRT. Thereby, the driving transistor DRT can supply from the high-potential power supply line P1 to the display element 40 the same amount of electric current as the electric current that is supplied from the video signal line SL.

On the basis of the supply of the ON signal from the second gate line GL2, the third switch SW3 is turned on, and the driving transistor DRT supplies a predetermined amount of current corresponding to a predetermined luminance from the high-potential power supply line P1 to the display element 40 via the third switch SW3 in accordance with the capacitance that is retained in the storage capacitance element Cs. Thereby, the display element 40 emits light with a predetermined luminance.

The display element 40 is composed of an organic EL element 40 (R, G, B) that is a self-luminous display element. Specifically, the red pixel PXR includes an organic EL element 40R which mainly emits light corresponding to a red wavelength. The green pixel PXG includes an organic EL element 40G which mainly emits light corresponding to a green wavelength. The blue pixel PXB includes an organic EL element 40B which mainly emits light corresponding to a blue wavelength.

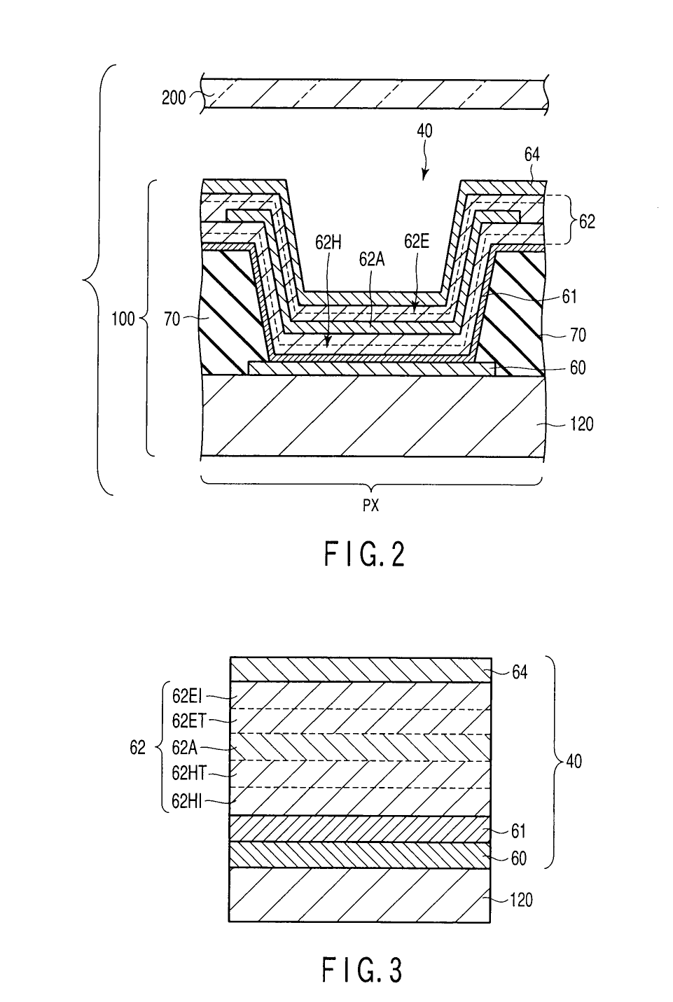

The respective kinds of organic EL elements 40 (R, G, B) have basically the same structure. For example, as shown in FIG. 2, the array substrate 100 includes the organic EL element 40 which is disposed on the major surface side of a wiring substrate 120. The wiring substrate 120 is configured such that pixel circuits of switches, driving transistors, etc., and various wiring lines (scanning lines, signal lines, power supply lines, etc.) are provided on an insulative support substrate such as a glass substrate or a plastic sheet.

The organic EL element 40 comprises a first electrode 60 which is disposed on the wiring substrate 120; a second electrode 64 which is disposed to be opposed to the first electrode 60 (i.e. disposed on the sealing substrate 200 side of the first electrode 60) and is common to a plurality of color pixels PX; and an organic active layer 62 which is held between the first electrode 60 and the second electrode 64.

An example of a more concrete structure of the organic EL element 40 is described. The first electrode 60 is disposed on the wiring substrate 120 in an independent island shape in association with each of the color pixels PX, and functions as an anode. The first electrode 60 may be composed of a multilayer structure in which a transmissive layer that is formed of a light-transmissive, electrically conductive material such as indium tin oxide (ITO), and a reflective layer that is formed of a light-reflective, electrically conductive material such as aluminum (Al) are stacked, or the first electrode 60 may be composed of a single reflective layer or a single transmissive layer.

The organic active layer 62 is disposed on the first electrode 60 and includes at least a light-emitting layer 62A. The organic active layer 62 may include functional layers other than the light-emitting layer 62A, for instance, a hole injection layer, a hole transport layer, a blocking layer, an electron transport layer, and a buffer layer. Alternatively, the organic active layer 62 may be composed of a single layer in which a plurality of functional layers are combined, or may be composed of a multilayer structure in which functional layers are stacked. In the organic active layer 62, it should suffice if the light-emitting layer is formed of an organic material, and the layers other than the light-emitting layer 62A may be formed of either an inorganic material or an organic material.

In the organic active layer 62, the functional layers other than the light-emitting layer 62A may be a common layer. In the example shown in FIG. 2, a common layer is disposed on each of the first electrode 60 side and the second electrode 64 side of the light-emitting layer 62A. One of the common layers, 62H, includes a hole injection layer and a hole transport layer, and the other common layer 62E includes an electron injection layer and an electron transport layer. The light-emitting layer 62A is formed of an organic compound having a function of emitting red, green or blue light.

The second electrode 64 is disposed on the organic active layer 62 of each color pixel PX and functions as a cathode. The second electrode 64 may be composed of a multilayer structure in which a semi-transmissive layer, which is formed of a mixture of silver (Ag) and magnesium (Mg), and a transmissive layer, which is formed of a light-transmissive, electrically conductive material such as ITO, are stacked. Alternatively, the second electrode 64 may be formed of a single semi-transmissive layer, or a single transmissive layer.

The array substrate 100 includes, in the active area 102, partition walls 70 which isolate at least neighboring color pixels PX (R, G, B). The partition walls 70 are disposed in lattice shapes or in stripe shapes in the active area 102 so as to cover peripheral edges of the first electrode 60. Thereby, the neighboring organic EL elements of different colors are isolated. The partition walls 70 are formed by patterning, for example, a resin material. The partition walls 70 are covered with the second electrode 64.

In this embodiment, the organic EL element 40 includes a carrier injection adjusting layer 61 which is disposed between the first electrode 60 and the organic active layer 62. The carrier injection adjusting layer 61 is formed of a material which exhibits such varistor characteristics (non-linear resistance characteristics) that a conduction current due to an applied voltage varies.

The carrier injection adjusting layer 61 will now be described in greater detail.

In an example shown in FIG. 3, the organic EL element 40 comprises a first electrode 60 disposed on the wiring substrate 120 and functioning as an anode; a carrier injection adjusting layer 61 disposed on the first electrode 60; a hole injection layer 62HI disposed on the carrier injection adjusting layer 61; a hole transport layer 62HT disposed on the hole injection layer 62HI; a light-emitting layer 62A disposed on the hole transport layer 62HT; an electron transport layer 62ET disposed on the light-emitting layer 62A; an electron injection layer 62EI disposed on the electron transport layer 62ET; and a second electrode 64 disposed on the electron injection layer 62ET and functioning as a cathode.

In the organic EL element 40, the hole mobility is higher than the electron mobility. Thus, if a voltage is applied between the first electrode 60 and the second electrode 64, the hole injection precedes in a low-voltage region. As a result, a state in which holes are excessive occurs in the light-emitting layer 62A.

To cope with this, as in the present embodiment, the carrier injection adjusting layer 61, which has such varistor characteristics that the resistance is high at a time of low voltage application and the resistance quickly decreases at a time of high voltage application, is provided between the first electrode 60 and the organic active layer 62. Thereby, as the voltage that is applied to the organic active layer 62 becomes lower, the hole injection from the first electrode 60 to the organic active layer 62 is suppressed so as to maintain a balance with the electrons that are injected in the organic active layer 62. Thus, the carrier balance in the light-emitting layer 62A is improved. In other words, at the time of low voltage application, the state of excessive holes in the light-emitting layer 62A is relaxed and, as a matter of course, the state of excessive electrons is suppressed.

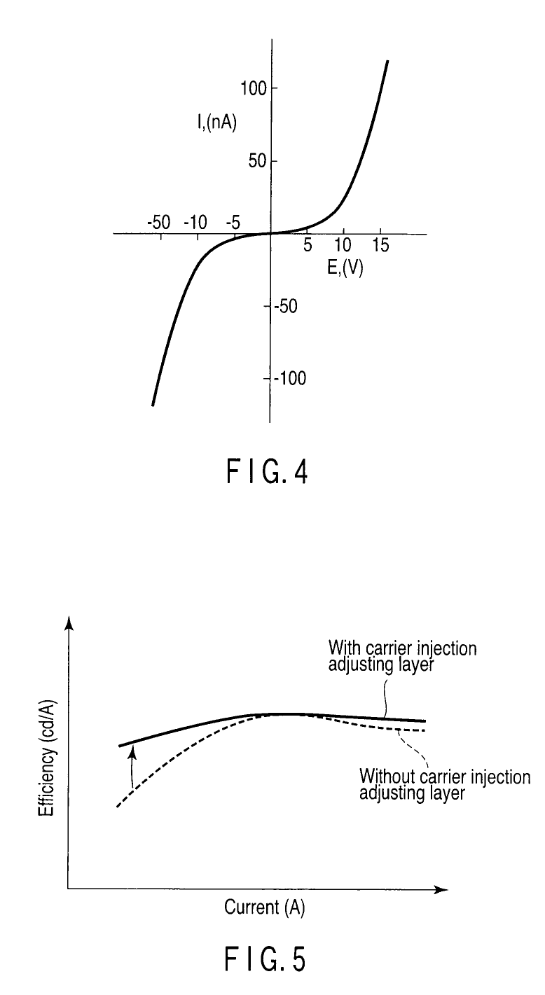

FIG. 4 shows an example of varistor characteristics (non-ohmic voltage/current characteristics) of the carrier injection adjusting layer 61, which is applicable in the present embodiment. Needless to say, the varistor characteristics vary depending on a principal material and the amount of an additive.

At the time of high voltage application, the electron injection and electron transport from the second electrode 64 increase. On the hole side, too, with a quick decrease in resistance of the carrier injection adjusting layer 61, the hole injection and hole transport from the first electrode 60 increase. Thus, a good carrier balance state can be maintained in the light-emitting layer 62A.

In short, the carrier balance can be optimized in a wide current range including a driving current range of the organic EL element. Accordingly, the light emission efficiency can be improved. Thereby, the lifetime can be increased.

The above-described carrier injection adjusting layer 61 can be formed of zinc oxide as a principal material. Specifically, for example, zinc oxide is used as a principal material, and bismuth, which is a low-melting-point metal, is used as a grain boundary forming layer. Manganese oxide or cobalt oxide, which is a transition metal, is added as an additive. Further, in the case of setting a varistor voltage at a high level, antimony oxide is added. In the case of setting the varistor voltage at a low level, aluminum oxide or titanium oxide is added. The addition amount thereof may properly be varied according to target varistor characteristics.

The above-described carrier injection adjusting layer 61 may be formed of grains which are obtained by coating the surfaces of electrically conductive grains or semiconductor grains with an electrically conductive resin. Specifically, pure gold grains, for instance, are applicable as electrically conductive grains. In addition, SiC, ZnO or BaTiO₃, for instance, is applicable as semiconductor grains. Polythiophene or polypyrrole, for instance, is applicable as electrically conductive resin.

Next, more concrete examples are described.

A first electrode 60 is formed on the wiring substrate 120. Specifically, the first electrode 60 of ITO is formed in association with each pixel by film formation and patterning of an electrically conductive material.

Then, using a target containing zinc oxide and an additive, a thin film is formed on the first electrode 60 by sputtering. Subsequently, this thin film is subjected to annealing, and a Schottky barrier is formed between the zinc oxide and additive. Thereby, a carrier injection adjusting layer 61 having varistor characteristics is formed.

Thereafter, on the carrier injection adjusting layer 61, amorphous carbon is formed as a hole injection layer 62HI, and ANPD is formed as a hole transport layer 62HT by an evaporation deposition method. Using a fine mask, a red light-emission layer material (host: Alq₃, dopant: DCM), a green light-emitting layer material (host: Alq₃, dopant: coumarin) and a blue light-emitting layer material (host: BH120, dopant: BD-102) are formed by evaporation deposition in association with a red pixel, green pixel and a blue pixel, thus forming light-emitting layers 62A of the respective pixels. On each light-emitting layer 62A, an electron transport layer 62ET and an electron injection layer 62EI are formed.

Thereafter, magnesium and silver are deposited by evaporation on the electron injection layer 62EI, and then ITO is deposited by evaporation, thus forming a cathode 64. Through these fabrication steps, a display device having a top-emission-type organic EL element is manufactured.

FIG. 5 shows measured current (A)/efficiency (cd/A) characteristics of the manufactured display device. According to the present embodiment (solid line in FIG. 5), a variation in efficiency, relative to a variation in current, is smaller than in the case of a display device (broken line in FIG. 5) having a device structure without a carrier injection adjusting layer. In particular, it has been confirmed that the efficiency at a time of low electric current is improved, and the current dependency of the carrier balance is improved, with an L/J curve being substantially flattened over a wide current range.

In this manner, the carrier balance is optimized over a wide current range from a low current to a high current. It has been confirmed that a variation in carrier balance in a lifetime test is suppressed, and the lifetime of the display device according to the present embodiment is 1.5 times longer than the display device having the device structure without a carrier injection adjusting layer.

As has been described above, according to the present embodiment, the carrier injection adjusting layer, which exhibits such non-linear resistance characteristics that the conductivity varies in accordance with a voltage, is disposed between the anode and the organic active layer (in particular, the hole injection layer). Thereby, the current dependency of the carrier balance of the light-emitting layer in the organic active layer is improved, and the lifetime can be increased.

The present invention is not limited directly to the above-described embodiment. In practice, the structural elements can be modified and embodied without departing from the spirit of the invention. Various inventions can be made by properly combining the structural elements disclosed in the embodiment. For example, some structural elements may be omitted from all the structural elements disclosed in the embodiment. Furthermore, structural elements in different embodiments may properly be combined.

What is claimed is:

1. A display device including a self-luminous display element, the display element comprising:
an anode;
a cathode disposed to be opposed to the anode;
an organic active layer disposed between the anode and the cathode; and
a carrier injection adjusting layer which is disposed between the anode and the organic active layer and exhibits non-linear resistance characteristics,
wherein the carrier injection adjusting layer suppresses injection of holes from the anode into the organic active layer in a manner to maintain a carrier balance with electrons, which are injected from the cathode into the organic active layer, as a voltage, which is applied to the organic active layer, becomes lower.

2. The display device according to claim 1, wherein the carrier injection adjusting layer is formed of zinc oxide as a principal material.

3. The display device according to claim 1, wherein the carrier injection adjusting layer is formed of grains which are obtained by coating surfaces of electrically conductive grains or semiconductor grains with an electrically conductive resin.

4. A display device including a self-luminous display element, the display element comprising:
an anode;
a cathode disposed to be opposed to the anode;
an organic active layer disposed between the anode and the cathode; and
a carrier injection adjusting layer which is disposed between the anode and the organic active layer and exhibits such varistor characteristics that a conduction current due to an applied voltage varies.
